(19) United States
(12) Patent Application Publication
(10) Pub. No.: US 2012/0145211 A1
(43) Pub. Date: Jun. 14, 2012

(54) THERMOELECTRIC DEVICE AND METHOD OF MANUFACTURING THE SAME

(75) Inventors: Sung Ho LEE, Gyeonggi-do (KR); Dong Hyeok Choi, Gyeonggi-do (KR); Yong Suk Kim, Gyeonggi-do (KR)

(73) Assignee: SAMSUNG ELECTRO-MECHANICS CO., LTD.

(21) Appl. No.: 13/305,251

(22) Filed: Nov. 28, 2011

(30) Foreign Application Priority Data
Dec. 9, 2010 (KR) 10-2010-0125280

(51) Int. Cl. H01L 35/28; H01L 35/34

(52) U.S. Cl. 136/200; 136/201

(57) ABSTRACT

The present invention provides a thermoelectric device including: thermoelectric sheets made of a thermoelectric semiconductor and laminated in multi-layers; and a metal sheet interposed between the thermoelectric sheets, and a method of manufacturing the same.

### CROSS REFERENCE TO RELATED APPLICATION

This application claims the benefit under 35 U.S.C. Section 119 of Korean Patent Application Serial No. 10-2010-0125280, entitled filed Dec. 9, 2010, which is hereby incorporated by reference in its entirety into this application.

### BACKGROUND OF THE INVENTION

1. Field of the Invention

The present invention relates to a thermoelectric device and a method of manufacturing the same, and more particularly, to a thermoelectric device capable of improving a thermoelectric figure of merit and securing mass production by having a structure in which a thermoelectric sheet and a metal sheet are laminated, and a method of manufacturing the same.

2. Description of the Related Art

Recently, there have been many studies on a thermoelectric device that can efficiently use energy since a sudden increase in use of fossil energy has caused global warming and energy depletion.

Here, a thermoelectric device has thermoelectric effects, that is, a Seebeck effect that an electromotive force is generated by using a temperature difference between both ends caused by a current applied from the outside and a Peltier effect that one end generates heat and the other end absorbs heat when a direct current is applied. That is, a thermoelectric device can be widely applied to the field of cooling and power generation.

For practical applications, a thermoelectric device has to be manufactured in the form of bulk or thick film with a volume of several mm³ to several cm³. This bulk thermoelectric device uses basic processes such as initial dissolution, crushing, and sintering and can be manufactured into a P-type semiconductor and an N-type semiconductor by addition of a dopant.

Meanwhile, performance of a thermoelectric device can be determined by measuring a thermoelectric figure of merit. At this time, there has been focus on developments such as refinement and improvement of sintered density of thermoelectric powder particles in order to improve a thermoelectric figure of merit of a bulk or thick film thermoelectric device.

However, there has been a problem such as a reduction in mass production of a thermoelectric device due to refinement and improvement of sintered density of thermoelectric powder particles.

### SUMMARY OF THE INVENTION

The present invention has been invented in order to overcome the above-described problems and it is, therefore, an object of the present invention to provide a thermoelectric device capable of improving a thermoelectric figure of merit and securing mass production, and a method of manufacturing the same.

In accordance with one aspect of the present invention to achieve the object, there is provided a thermoelectric device including: thermoelectric sheets made of a thermoelectric semiconductor and laminated in multi-layers; and a metal sheet interposed between the thermoelectric sheets.

Here, the thermoelectric sheet and the metal sheet may be alternately laminated on each other and provided at the same rate.

Further, the metal sheet may be provided at a smaller rate than the thermoelectric sheet by being partially disposed between the laminated thermoelectric sheets.

Further, the thermoelectric sheets laminated in multi-layers may be made of the same thermoelectric semiconductor material.

Further, the metal sheet may have a thickness range of 0.1 μm to 10 μm.

Further, the thermoelectric sheet may have a thickness range of 1 μm to 1000 μm.

Further, the metal sheet may have a smaller area than the thermoelectric sheet.

Further, the thermoelectric device may further include an additional thermoelectric sheet spaced apart from the metal sheet and disposed on the thermoelectric sheet exposed by the metal sheet.

In accordance with another aspect of the present invention to achieve the object, there is provided a method of manufacturing a thermoelectric device including the steps of: forming a thermoelectric sheet and a metal sheet, respectively; forming a preliminary thermoelectric device by laminating the thermoelectric sheet and the metal sheet; compressing the preliminary thermoelectric device; and forming a thermoelectric device by cutting the compressed preliminary thermoelectric device.

Here, the thermoelectric sheet may be formed through a roll printing process.

Further, the metal sheet may be formed through a roll printing process.

Further, the thermoelectric sheet and the metal sheet may be alternately laminated on each other and laminated at the same rate.

Further, the metal sheet may be laminated at a smaller rate than the thermoelectric sheet by being partially disposed between the laminated thermoelectric sheets.

Further, the metal sheet may have a smaller area than the thermoelectric sheet.

Further, in the step of forming the preliminary thermoelectric device by laminating the thermoelectric sheet and the metal sheet, an additional thermoelectric sheet may be further laminated on the thermoelectric sheet exposed by the metal sheet.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a perspective view of a thermoelectric module having a thermoelectric device in accordance with an embodiment of the present invention;

FIG. 2 is a perspective view of a thermoelectric device in accordance with a first embodiment of the present invention;

FIG. 3 is a perspective view of a thermoelectric device in accordance with a second embodiment of the present invention; and

FIGS. 4 to 6 are views for explaining a process of manufacturing a thermoelectric device in accordance with a third embodiment of the present invention.

### DETAILED DESCRIPTION OF THE PREFERABLE EMBODIMENTS

Hereinafter, embodiments of the present invention will be described in detail with reference to the accompanying drawings. The following embodiments are provided as examples to fully convey the spirit of the invention to those skilled in the art.

Therefore, the present invention should not be construed as limited to the embodiments set forth herein and may be embodied in different forms. And, the size and the thickness of an apparatus may be overdrawn in the drawings for the convenience of explanation. The same components are represented by the same reference numerals hereinafter.

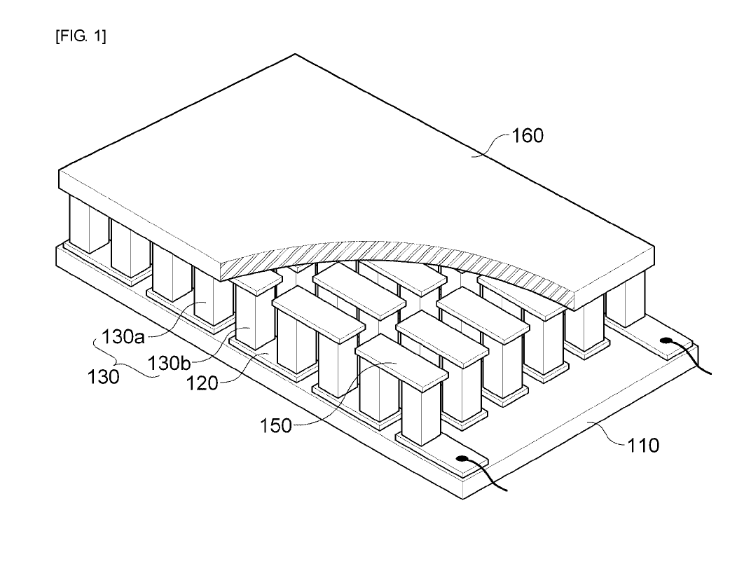

FIG. 1 is a perspective view of a thermoelectric module having a thermoelectric device in accordance with an embodiment of the present invention.

Referring to FIG. 1, a thermoelectric module may include first and second substrates 110 and 160 facing each other while being spaced apart from each other, first and second electrodes 120 and 150 disposed on inner surfaces of the first and second substrate 110 and 160, respectively, and a thermoelectric device 130 interposed between the first and second substrates 110 and 160.

The first and second substrates 110 and 160 may play a role of supporting the thermoelectric device 130 and the first and second electrodes 120 and 150. Moreover, when a plurality of thermoelectric devices 130 are provided, the first and second substrate 110 and 160 may perform a role of connecting the plurality of thermoelectric devices 130.

Further, the first substrate 110 and the second substrate 160 may be bonded to an external device to play a role of absorbing heat from the outside or radiating heat to the outside through heat exchange of the thermoelectric device 130. For this, the first and second substrates 110 and 160 may be made of high thermal conductivity ceramic, for example, alumina. Alternatively, the first and second substrates 110 and 160 may be made of metal with excellent thermal conductivity, for example, aluminum, copper, and so on.

Meanwhile, the thermoelectric device 130 may include a P-type semiconductor 130a and an N-type semiconductor 130b. At this time, the P-type semiconductor 130a and the N-type semiconductor 130b may be alternately arranged on the same plane. At this time, the first and second electrodes 120 and 150 may be disposed to face each other while the thermoelectric device 130 interposed therebetween. At this time, a pair of P-type and N-type semiconductors 130a and 130b may be electrically connected by the first electrode 120 disposed on lower surfaces thereof, and adjacent another pair of P-type and N-type semiconductors 130a and 130b may be electrically connected by the second electrode 150 disposed on upper surfaces thereof.

In addition, the first and second electrodes 120 and 150 may be connected to an external power supply unit by a wire 170 to supply or receive power to or from the external power supply unit. That is, the first and second electrodes 120 and 150 can supply power to the external power supply unit when the thermoelectric module plays a role of a power generation device and receive power from the external power supply unit when the thermoelectric module plays a role of a cooling device.

Since the thermoelectric module includes the thermoelectric device having a structure in which the thermoelectric sheet and the metal sheet are laminated, energy conversion efficiency of the thermoelectric module can be improved. This is because the thermoelectric device can maintain at least electrical conductivity and improve a thermoelectric figure of merit by induction of phonon scattering.

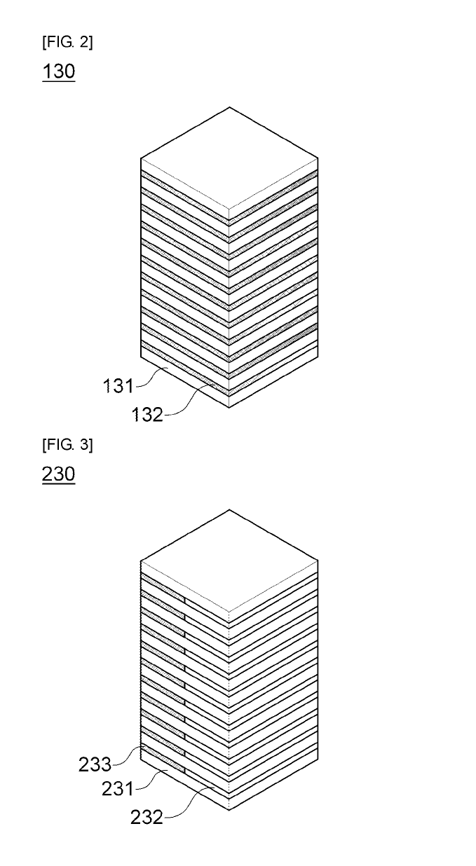

Hereinafter, a thermoelectric device in accordance with a first embodiment of the present invention will be more specifically described with reference to FIG. 2.

FIG. 2 is a perspective view of a thermoelectric device in accordance with a first embodiment of the present invention.

Referring to FIG. 2, a thermoelectric device 130 in accordance with a first embodiment of the present invention may include thermoelectric sheets 131 laminated in multi-layers and a metal sheet 132 interposed between the thermoelectric sheets 131.

The thermoelectric sheet 131 may be made of a thermoelectric semiconductor. Here, the thermoelectric sheets 131 laminated in multi-layers may be made of the same thermoelectric semiconductor material. For example, the thermoelectric semiconductor material may be bismuth (Bi), antimony (Sb), tellurium (Te), selenium (Se), and so on. For a concrete example, the thermoelectric semiconductor material may be Bi₂Te₃, ZnSb₃, CoSb₃, Mg₂Si, Fe₂Si, and so on. Here, since the thermoelectric sheets 131 are made of the same semiconductor material, it is possible to simplify process procedures.

Meanwhile, a thermoelectric figure of merit of a general thermoelectric device is as the following equation 1.

$$zT = \frac{{α}^{2} σ}{k} T \qquad [ Equation 1 ]$$

Here, zT represents a thermoelectric figure of merit, a represents a Seebeck coefficient, σ represents electrical conductivity, k represents thermal conductivity, and T represents a temperature.

As in the equation 1, since electrical conductivity and thermal conductivity are in inverse proportion to each other, electrons have to smoothly move from an end to an opposite end of the thermoelectric device 130 in order to improve zT, a thermoelectric figure of merit, and thus it is required to scatter phonons. This is because the electron is a medium that moves electricity with heat and the phonon is a medium that moves heat.

Generally, the electron has a wavelength range of 10 nm to 100 nm, and the phonon has a wavelength of 1 nm. That is, since the phonon has a shorter wavelength than the electron, scattering may occur in a boundary part of each layer of the thermoelectric sheets 131 laminated in multi-layers. Due to this, the thermoelectric figure of merit, zT can be improved. That is, since the thermoelectric device 130 is formed of the thermoelectric sheets 131 laminated in multi-layers so that scattering of phonons occurs, the thermoelectric figure of merit of the thermoelectric device 130 can be improved.

The thermoelectric sheet 131 may have a thickness range of 1 μm to 1000 μm. Here, it may be technically difficult to form the thermoelectric sheet 131 with a thickness of less than 1 μm through the existing process. On the other hand, when the thermoelectric sheet 131 is formed with a thickness of greater than 1000 μm, a phonon scattering effect may be reduced.

The metal sheet 132 may be interposed between the laminated thermoelectric sheets 131. Here, the thermoelectric sheet 131 and the metal sheet 132 may be alternately laminated on each other. That is, the thermoelectric device 130 may include the thermoelectric sheet 131 and the metal sheet 132 at the same rate. Alternatively, the metal sheet 132 may be partially disposed between the laminated thermoelectric sheets 131. A plurality of thermoelectric sheets 131 and one metal sheet 132 may be repeatedly or irregularly laminated. That is, the thermoelectric device 130 may include the metal sheet 132 at a smaller rate than the thermoelectric sheet 131.

The metal sheet 132 may be interposed between the thermoelectric sheets 131 to play a role of maintaining movement of the electron in an initial state and suppressing movement of the phonon. That is, when the thermoelectric device 130 is formed of the thermoelectric sheets 131 laminated in multi-layers, the metal sheet 132 can maintain at least electrical conductivity and reduce thermal conductivity by preventing the free movement of the phonon on the interface between the thermoelectric sheets 131.

The metal sheet 132 may be made of a material that can prevent the free movement of the phonon. Here, for example, the metal sheet 132 may be made of transition metal, rare-earth metal, and so on.

The metal sheet 132 may be formed to have a thickness range of 0.1 μm to 10 μm. Here, it is difficult to form the metal sheet 132 with a thickness of less than 0.1 μm. On the other hand, when the metal sheet 132 is formed with a thickness of greater than 10 μm, a phonon scattering effect may be reduced.

Therefore, as in the embodiment of the present invention, since the thermoelectric device is formed to have a structure in which the thermoelectric sheet and the metal sheet are laminated, it is possible to maintain at least electrical conductivity and improve a thermoelectric figure of merit by inducing phonon scattering.

FIG. 3 is a perspective view of a thermoelectric device in accordance with a second embodiment of the present invention. Here, a thermoelectric device in accordance with a second embodiment of the present invention may have the same technical configuration as the above-described thermoelectric device in accordance with a first embodiment except for a shape of a metal sheet and further inclusion of an additional thermoelectric sheet. Accordingly, a repeated description of a first embodiment will be omitted.

Referring to FIG. 3, a thermoelectric device 230 in accordance with a second embodiment of the present invention may include thermoelectric sheets 231 laminated in multi-layers and a metal sheet 232 interposed between the thermoelectric sheets 231.

Here, the metal sheet 232 may have a smaller area than the thermoelectric sheet 231. Accordingly, the metal sheet 232 may be formed to expose the thermoelectric sheet 231 when laminated on the thermoelectric sheet 231.

An additional thermoelectric sheet 233 may be further disposed on the thermoelectric sheet 231 exposed by the metal sheet 232. That is, the metal sheet 232 and the additional thermoelectric sheet 233 may be disposed in parallel on the thermoelectric sheet 231. Here, a side surface of the metal sheet 232 and a side surface of the additional thermoelectric sheet 233 may be formed to be bonded to each other. At this time, the thermoelectric sheet 231 and the additional thermoelectric sheet 233 may be made of the same thermoelectric semiconductor. Accordingly, since a bonding surface area between the laminated thermoelectric sheet 232 and the additional thermoelectric sheet 233 and the metal sheet 232 can be increased so that a phonon scattering effect can be increased, it is possible to increase a thermoelectric figure of merit of the thermoelectric device 230.

Accordingly, as in the embodiment of the present invention, in forming the thermoelectric device having a structure in which the thermoelectric sheet and the metal sheet are laminated, since an area of the metal sheet is reduced and an additional thermoelectric sheet is disposed in a region exposed by the metal sheet, it is possible to improve a thermoelectric figure of merit by increasing phonon scattering due to an increase in the bonding surface area between the thermoelectric sheet and the metal sheet.

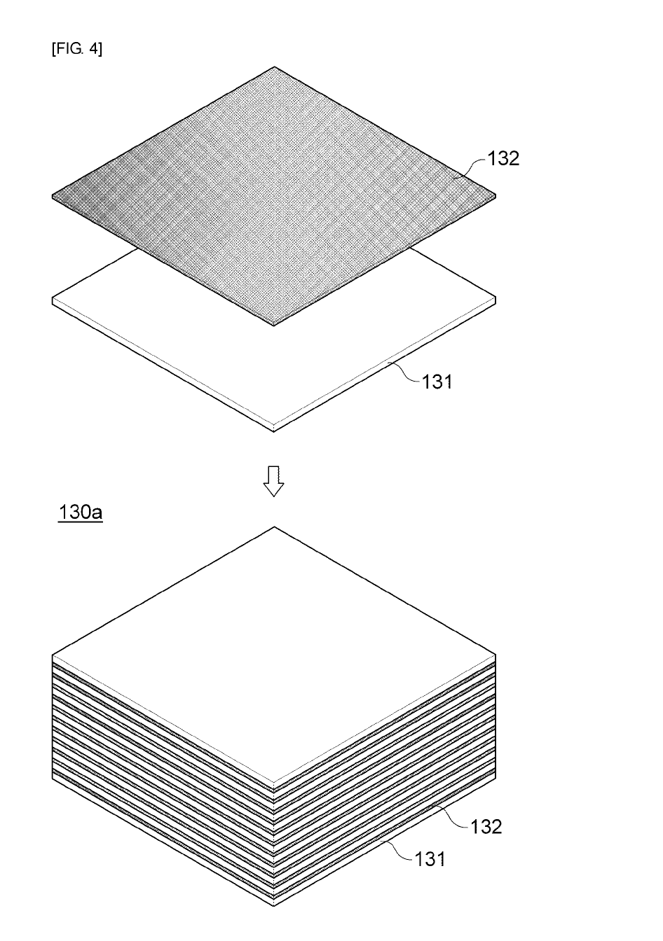

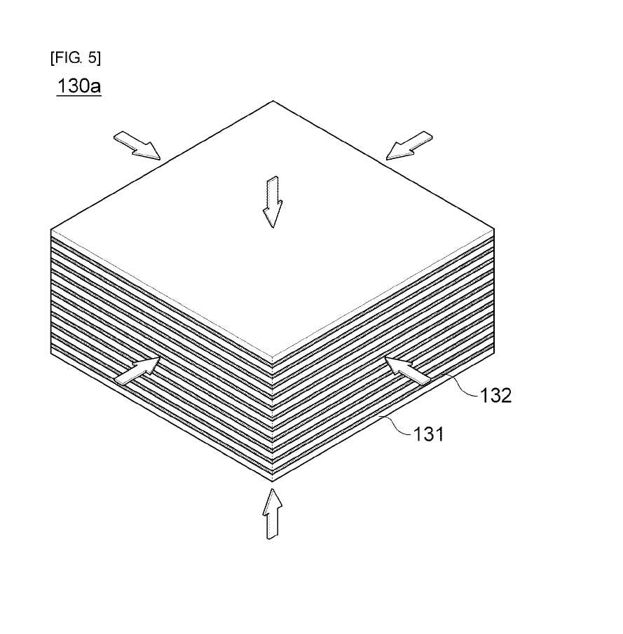

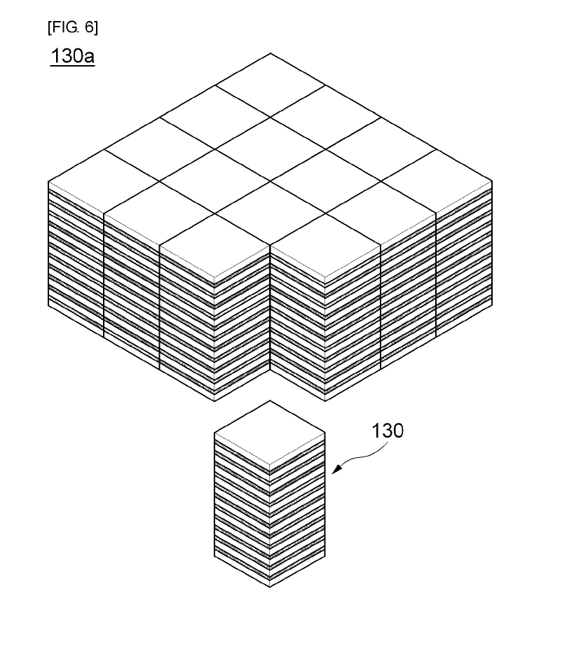

Hereinafter, a process of manufacturing a thermoelectric device will be described with reference to FIGS. 4 to 6.

FIGS. 4 to 6 are views for explaining a process of manufacturing a thermoelectric device in accordance with a third embodiment of the present invention.

As in FIG. 4, in order to form a thermoelectric device 130, first, a thermoelectric sheet 131 and a metal sheet 132 are formed, respectively. Each of the thermoelectric sheet 131 and the metal sheet 132 may be formed through a ceramic process. Specifically, in order to manufacture the thermoelectric sheet 131, first, thermoelectric slurry is manufactured. The thermoelectric slurry may be formed by mixing thermoelectric semiconductor powder, a binder, and a solvent. The thermoelectric sheet 131 may be manufactured by being separated from a carrier film after being applied onto the carrier film through a roll printing method and dried.

Meanwhile, in order to manufacture the metal sheet 132, metal slurry is formed by mixing metal powder, a binder, and a solvent. After that, the metal sheet 132 may be formed by being separated from a carrier film after being applied onto the carrier film through a roll printing method and dried.

Here, each of the thermoelectric sheet 131 and the metal sheet 132 may have an area corresponding to a plurality of thermoelectric devices 130.

After that, a preliminary thermoelectric device 130a may be formed by laminating the thermoelectric sheet 131 and the metal sheet 132. Here, the thermoelectric sheet 131 and the metal sheet 132 may be alternately laminated on each other. That is, the thermoelectric sheet 131 and the metal sheet 132 may be provided at the same rate.

Alternatively, the preliminary thermoelectric device 130a may be formed by repeatedly performing a first laminating process of laminating a plurality of thermoelectric sheets 131 and a second laminating process of laminating one metal sheet 132 on the plurality of thermoelectric sheets 131. That is, the preliminary thermoelectric device 130a may be partially disposed between the laminated thermoelectric sheets 131. Accordingly, in the preliminary thermoelectric device 130a, the metal sheet 132 may be provided at a smaller rate than the thermoelectric sheet 131.

In the drawing, even though it is described and illustrated that the thermoelectric sheet 131 and the metal sheet 132 have the same area, it is not limited thereto. That is, the metal sheet 132 may have a smaller area than the thermoelectric sheet 131. Here, the metal sheet 132 and an additional thermoelectric sheet 233 of FIG. 3 may be laminated in parallel on the thermoelectric sheet 131. At this time, the area of the thermoelectric sheet 131 may be equal to a combined area of the metal sheet 132 and the additional metal sheet 233 of FIG. 3. Accordingly, it may be expected that a bonding surface area between the thermoelectric sheet 131 and the metal sheet 132 is increased.

Referring to FIG. 6, a bulk thermoelectric device with a volume of several mm³ to several cm³ may be formed by compressing the preliminary thermoelectric device 130a.

In addition, referring to FIG. 7, when the preliminary thermoelectric device 130a is formed of the thermoelectric sheet 131 and the metal sheet 132, each of which has the area corresponding to the plurality of thermoelectric devices, a plurality of bulk thermoelectric devices 130 may be formed through one process by compressing the preliminary thermoelectric device 130a and cutting the compressed preliminary thermoelectric device 130a by each unit.

Therefore, as in the embodiment of the present invention, it is possible to achieve mass production of the thermoelectric device by manufacturing the thermoelectric sheet and the metal sheet through a ceramic process and laminating the thermoelectric sheet and the metal sheet.

Further, as in the embodiment of the present invention, since the thermoelectric device is formed through a laminating process of the thermoelectric sheet and the metal sheet, it is possible to improve design freedom of the thermoelectric device by easily changing a thickness and a shape of the thermoelectric device.

Further, as in the embodiment of the present invention, it is possible to form the plurality of thermoelectric devices through one process by forming the thermoelectric device with the thermoelectric sheet and the metal sheet, each of which has the area corresponding to the plurality of thermoelectric devices.

The thermoelectric device in accordance with an embodiment of the present invention is formed to have a structure in which the thermoelectric sheet and the metal sheet are laminated. Therefore, it is possible to maintain at least electrical conductivity and improve a thermoelectric figure of merit by induction of phonon scattering.

Further, the thermoelectric device in accordance with an embodiment of the present invention is formed through a laminating process of the thermoelectric sheet and the metal sheet after manufacturing the thermoelectric sheet and the metal sheet through a ceramic process or a metal process using a rapid cold method. Therefore, it is possible to secure mass production.

What is claimed is:

1. A thermoelectric device comprising:
thermoelectric sheets made of a thermoelectric semiconductor and laminated in multi-layers; and
a metal sheet interposed between the thermoelectric sheets.

2. The thermoelectric device according to claim 1, wherein the thermoelectric sheet and the metal sheet are alternately laminated on each other and provided at the same rate.

3. The thermoelectric device according to claim 1, wherein the metal sheet is provided at a smaller rate than the thermoelectric sheet by being partially disposed between the laminated thermoelectric sheets.

4. The thermoelectric device according to claim 1, wherein the thermoelectric sheets laminated in multi-layers are made of the same thermoelectric semiconductor material.

5. The thermoelectric device according to claim 1, wherein the metal sheet has a thickness range of 0.1 μm to 10 μm.

6. The thermoelectric device according to claim 1, wherein the thermoelectric sheet has a thickness range of 1 μm to 1000 μm.

7. The thermoelectric device according to claim 1, wherein the metal sheet has a smaller area than the thermoelectric sheet.

8. The thermoelectric device according to claim 7, further comprising: an additional thermoelectric sheet spaced apart from the metal sheet and disposed on the thermoelectric sheet exposed by the metal sheet.

9. A method of manufacturing a thermoelectric device comprising:
forming a thermoelectric sheet and a metal sheet, respectively;
forming a preliminary thermoelectric device by laminating the thermoelectric sheet and the metal sheet;
compressing the preliminary thermoelectric device; and
forming a thermoelectric device by cutting the compressed preliminary thermoelectric device.

10. The method of manufacturing a thermoelectric device according to claim 9, wherein the thermoelectric sheet is formed through a roll printing process.

11. The method of manufacturing a thermoelectric device according to claim 9, wherein the metal sheet is formed through a roll printing process.

12. The method of manufacturing a thermoelectric device according to claim 9, wherein the thermoelectric sheet and the metal sheet are alternately laminated on each other and laminated at the same rate.

13. The method of manufacturing a thermoelectric device according to claim 9, wherein the metal sheet is laminated at a smaller rate than the thermoelectric sheet by being partially disposed between the laminated thermoelectric.

14. The method of manufacturing a thermoelectric device according to claim 9, wherein the metal sheet has a smaller area than the thermoelectric sheet.

15. The method of manufacturing a thermoelectric device according to claim 10, wherein, in forming the preliminary thermoelectric device by laminating the thermoelectric sheet and the metal sheet, an additional thermoelectric sheet is further laminated on the thermoelectric sheet exposed by the metal sheet.
